(19) United States
(12) Patent Application Publication
(10) Pub. No.: US 2023/0064228 A1
(43) Pub. Date: Mar. 2, 2023

(54) RECORDING MEDIUM, AND SYSTEM

(71) Applicants: Topcon Corporation, Tokyo (JP); RIKEN, Saitama (JP)

(72) Inventors: Satoshi WADA, Wako-shi, Saitama (JP); Atsushi SHINJO, Wako-shi, Saitama (JP); Takayo OGAWA, Wako-shi, Saitama (JP); Takeharu MURAKAMI, Wako-shi, Saitama (JP); Yasufumi FUKUMA, Wako-shi, Saitama (JP); Zaxing MAO, Itabashi-ku, Tokyo (JP); Satoshi YANOBE, Itabashi-ku, Tokyo (JP); Toshio YAMADA, Itabashi-ku, Tokyo (JP)

(73) Assignees: Topcon Corporation, Tokyo (JP); RIKEN, Saitama (JP)

(21) Appl. No.: 17/794,623

(22) PCT Filed: Jan. 20, 2021
(86) PCT No.: PCT/JP2021/001750

§ 371 Date: Jul. 22, 2022

(30) Foreign Application Priority Data
Feb. 7, 2020 (JP) 2020-019669

(51) Int. Cl. G06F 30/13; G01C 11/02

(52) U.S. Cl. CPC G06F 30/13; G01C 11/02

(57) ABSTRACT

One aspect example is a system for photogrammetry of a building. A memory stores design data and physical material data. The design data includes virtual material information on attributes for each of virtual materials of a virtual building. The physical material data is on the attributes for each of physical materials and generated based on measured data acquired from a physical building constructed on the basis of the design data. A material associating processor is configured to generate pairs of virtual and physical materials by determining an association between the virtual materials and the physical materials based on the virtual material information and the physical material data. An attribute associating processor is configured to determine an association between the virtual material information and the physical material data in accordance with the attributes for each of the pairs.

### TECHNICAL FIELD

The present disclosure relates generally to a data structure, a recording medium, and a system for building photogrammetry.

### BACKGROUND OF THE INVENTION

Photogrammetry (also referred to as reality capture or the like) is a technology of creating a three dimensional model by acquiring data of a physical object (also referred to as a tangible object, a real object, a real tangible object, etc.) with a digital camera or a laser scanner. Photogrammetry is used in various kinds of fields such as measurement, virtual reality, and augmented reality (see, for example, the Patent Documents 1 and 2 listed below). Applications of photogrammetry in the fields of architecture (building construction) and civil engineering have attracted attention in recent years.

In the field of architecture, the application of photogrammetry have been promoted for construction control or management, maintenance control or management, repair control or management, etc., and attempts have been made to combine photogrammetry with the following technologies (see, for example, the Patent Documents 3 to 12 listed below): a mobile object (also referred to as a moving object, a moving body, etc.) such as an unmanned aerial vehicle (UAV) (or commonly known as a drone); a surveying instrument such as a total station; data processing technologies such as structure from motion (SfM), multi-view stereo (MVS), simultaneous localization and mapping (SLAM), and the like: and building information modeling (BIM).

The practical application and operation of such an integrated system in these fields require integrated, efficient and consistent management of various kinds of data and information. However, such management methods and systems have not yet been realized.

### PRIOR ART DOCUMENTS

### Patent Documents

|PATENT DOCUMENT 1| United States Patent Application Publication No. 2016/0034137

|PATENT DOCUMENT 2| European Patent Application Publication No. 3522003

|PATENT DOCUMENT 3| Japanese Unexamined Patent Application Publication No. 2018-116572

|PATENT DOCUMENT 4| Japanese Unexamined Patent Application Publication No. 2018-119882

|PATENT DOCUMENT 5| Japanese Unexamined Patent Application Publication No. 2018-124984

|PATENT DOCUMENT 6| Japanese Unexamined Patent Application Publication No. 2018-151964

|PATENT DOCUMENT 7| Japanese Unexamined Patent Application Publication No. 2019-023653

|PATENT DOCUMENT 8| Japanese Unexamined Patent Application Publication No. 2019-105789

|PATENT DOCUMENT 9| Japanese Unexamined Patent Application Publication No. 2019-194883

|PATENT DOCUMENT 10| Japanese Unexamined Patent Application Publication No. 2019-219206

|PATENT DOCUMENT 11| Japanese Unexamined Patent Application Publication No. 2020-004278

|PATENT DOCUMENT 12| Japanese Unexamined Patent Application Publication No. 2020-008423

### BRIEF SUMMARY OF THE INVENTION

### Problem to be Solved by the Invention

One object of the present disclosure is to provide a new technique or technology for practical application and operation of building photogrammetry.

### Means for Solving the Problem

Some aspect examples are a structure of data to be processed by a building photogrammetry system, the structure of data comprising: design data prepared in advance that includes virtual material information on a plurality of attributes for each of a plurality of virtual materials of a virtual building; and physical material data on the plurality of the attributes for each of a plurality of physical materials, the physical material data being generated based on measured data acquired from a physical building constructed on the basis of the design data, wherein the structure of data is used for: a material associating process of determining an association between the plurality of the virtual materials and the plurality of the physical materials based on the virtual material information and the physical material data; and an attribute associating process of determining an association between the virtual material information and the physical material data in accordance with the plurality of the attributes for each of a plurality of pairs of virtual and physical materials determined by the material associating process.

Some aspect examples are a computer-readable non-transitory recording medium that records data to be processed by a building photogrammetry system, wherein the data has a structure comprising: design data that includes virtual material information on a plurality of attributes for each of a plurality of virtual materials of a virtual building; and physical material data on the plurality of the attributes for each of a plurality of physical materials, the physical material data being generated based on measured data acquired from a physical building constructed on the basis of the design data, and the data is used for: a material associating process of determining an association between the plurality of the virtual materials and the plurality of the physical materials based on the virtual material information and the physical material data; and an attribute associating process of determining an association between the virtual material information and the physical material data in accordance with the plurality of the attributes for each of a plurality of pairs of virtual and physical materials determined by the material associating process.

Some aspect examples are a program for causing a computer included in a building photogrammetry system, to function as a data receiving processor, a material associating processor, and an attribute associating processor, wherein the data receiving processor is configured to receive design data and physical material data, the design data including virtual material information on a plurality of attributes for each of a plurality of virtual materials of a virtual building, and the physical material data being on the plurality of the attributes for each of a plurality of physical materials and being generated based on measured data acquired from a physical building constructed on the basis of the design data; the material associating processor is configured to perform determination of an association between the plurality of the virtual materials and the plurality of the physical materials, based on the virtual material information and the physical material data; and the attribute associating processor is configured to perform determination of an association between the virtual material information and the physical material data on the basis of the plurality of the attributes for each of a plurality of pairs of a virtual material and a physical material established by the material associating processor.

Some aspect examples are a computer-readable non-transitory recording medium that stores a program of an aspect example.

Some aspect examples are a system for photogrammetry of a building, comprising: a memory that stores design data and physical material data, the design data including virtual material information on a plurality of attributes for each of a plurality of virtual materials of a virtual building, and the physical material data being on the plurality of the attributes for each of a plurality of physical materials and being generated based on measured data acquired from a physical building constructed on the basis of the design data; a material associating processor configured to generate a plurality of pairs of virtual and physical materials by determining an association between the plurality of the virtual materials and the plurality of the physical materials based on the virtual material information and the physical material data; and an attribute associating processor configured to determine an association between the virtual material information and the physical material data in accordance with the plurality of the attributes for each of the plurality of the pairs.

### Effect of the Invention

According to an aspect example, a new technique or technology for practical application and operation of building photogrammetry is provided.

### BRIEF DESCRIPTION OF THE SEVERAL VIEWS OF THE DRAWING

FIG. 1 is a diagram of an example of a configuration of a system according to an aspect example.

FIG. 2 is a diagram of an example of a configuration of virtual material information according to an aspect example.

FIG. 3 is a diagram of an example of a data structure of virtual material information according to an aspect example.

FIG. 4 is a diagram of an example of a configuration of physical material data according to an aspect example.

FIG. 5 is a diagram of an example of a data structure of physical material data according to an aspect example.

FIG. 6 is a diagram illustrating an example of material associating process executed by a system according to an aspect example.

FIG. 7 is a diagram illustrating an example of attribute associating process executed by a system according to an aspect example.

### DETAILED DESCRIPTION OF THE INVENTION

The present disclosure describes some aspect examples of a data structure (data format), a recording medium on which data having a structure (format) is recorded, a program, a recording medium on which a program is recorded, and a system. While some aspect examples may be used to properly or suitably put into practical use and operate a building photogrammetry system (building reality capture system), the aspect examples may also be applied to a photogrammetry system in any other fields. In addition, matters and items described in the documents cited in the present disclosure (the present specification) and any other known technologies or techniques may be employed in the aspect examples described herein.

At least one or more of the functions of the elements described in the present disclosure are implemented by using a circuit configuration (or circuitry) or a processing circuit configuration (or processing circuitry). The circuitry or the processing circuitry includes any of the followings, all of which are configured and/or programmed to execute at least one or more functions disclosed herein: a general purpose processor, a dedicated processor, an integrated circuit, a central processing unit (CPU), a graphics processing unit (GPU), an application specific integrated circuit (ASIC), a programmable logic device (e.g., a simple programmable logic device (SPLD), a complex programmable logic device (CPLD), or a field programmable gate array (FPGA)), a conventional circuit configuration or circuitry, and any combination of these. A processor is considered to be processing circuitry or circuitry that includes a transistor and/or another circuitry. In the present disclosure, circuitry, a unit, a means, or a term similar to these is hardware that executes at least one or more functions disclosed herein, or hardware that is programmed to execute at least one or more functions disclosed herein. Hardware may be the hardware disclosed herein, or alternatively, known hardware that is programmed and/or configured to execute at least one or more functions described herein. In the case where the hardware is a processor, which may be considered as a certain type of circuitry, then circuitry, a unit, a means, or a term similar to these is a combination of hardware and software. In this case, the software is used to configure the hardware and/or the processor.

Any two or more of the aspect examples described herein may be combined in any manner. For example, any two or more aspect examples may be at least partially combined.

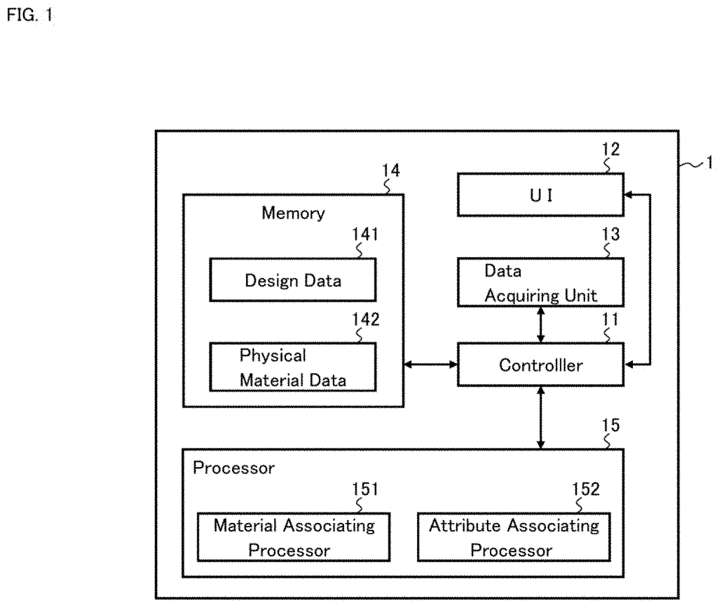

FIG. 1 shows a configuration example of the system according to an aspect example. The system 1 is included in a building photogrammetry system. The building photogrammetry system has the function of measuring an actual building and acquiring digital data. The building photogrammetry system of the present aspect example (also referred to as the system 1) is configured to generate a data structure (data format) for facilitating comparison between measured data of an actual building and design data thereof. The photogrammetry system of the present aspect example (the system 1) includes, for example, a data management system and a measurement system described later.

The system 1 according to the present aspect example includes at least the memory 14 and the processor 15, and may further includes the controller 11, the user interface (UI) 12, and the data acquiring unit 13.

The controller 11 is configured to execute various kinds of control processing of the system 1. The controller 11 is implemented, for example, by the cooperation of hardware including a processor and control software. The controller 11 may be included in a single computer or decentralized among two or more computers.

The user interface 12 includes, for example, a display device, an operation device, an input device, and the like. The user interface 12 of some aspect examples includes a graphical user interface (GUI) configured with hardware and software such as a touch screen, a pointing device, and computer graphics software. The user interface 12 may be included in a single computer or decentralized among two or more computers.

The data acquiring unit 13 is configured to execute either one or both of data generation and data reception. The data generation function includes, for example, any of the following functions: a function of acquiring data from a physical object; a function of processing data acquired from a physical object; a function of generating data using a computer; and a function of processing data generated in advance.

The function of acquiring data from a physical object may include, for example, either one or both of the following functions: a function of photographing the physical object with a camera (e.g., an omnidirectional camera, also known as a 360-degree camera) or a video camera (e.g., an omnidirectional video camera, also known as a 360-degree video camera) mounted on a mobile object such as an unmanned aerial vehicle (UAV) or carried by a person; and a function of acquiring data by scanning the physical object with a scanner such as a laser scanner or a total station. The data acquiring unit 13 having the function of acquiring data from a physical object may include one or more measuring apparatuses.

The function of processing data acquired from a physical object may be implemented, for example, by using at least a processor, and includes a function of applying a predetermined process to a photographed image or scan data of the physical object to generate other data. An example of this function is a data processing function implemented with any of SfM, MVS, SLAM (V-SLAM, or Visual SLAM) and the like described above. Another example is a data processing function with a learned model constructed using machine learning. The data acquiring unit 13 having the function of processing data acquired from a physical object may be included in a single computer or decentralized among two or more computers.

The function of generating data using a computer includes, for example, a data generating function with computer graphics, such as a function of generating data using a BIM application and a function of generating data using a computer-aided design (CAD) application. Hereinafter, data generated using a BIM application will be referred to as BIM data, and data generated using a CAD application will be referred to as CAD data. In addition to these functions, the function of generating data using a computer may include a function of generating data using various kinds of applications relating to architecture or construction such as a construction control or management application, a maintenance control or management application, and a repair control or management application. The data acquiring unit 13 having the function of generating data using a computer may be included in a single computer or decentralized among two or more computers.

The function of processing data generated in advance is implemented, for example, by using at least a processor, and includes a function of generating other data by applying a predetermined process to data of a physical object that has been acquired and/or processed in the past by any of the system 1, another apparatus, and another system. The technique or technology applicable to the function of processing data generated in advance may be the same as the technique or technology applicable to the function of processing data acquired from a physical object. BIM data is an example of the data generated in advance. The data acquiring unit 13 having the function of processing data generated in advance may be included in a single computer or decentralized among two or more computers.

The data reception function is a function of receiving data from the outside. The data reception function may be implemented, for example, by using a communication device for performing data communication with an external device, an external system, an external database, and the like. In addition to or in place of this, the data reception function may be implemented by using a drive device for reading out data recorded on a recording medium. The data received from the outside by the data acquiring unit 13 may be, for example, data generated by using a computer (e.g., BIM data, CAD data, etc.), or data that has been acquired and/or processed in the past by any of the system 1, another apparatus, and another system. The recording medium that can be employed for the data reception function is a computer-readable non-transitory recording medium, and examples thereof may include a magnetic disk, an optical disk, a magneto-optical disk, a semiconductor memory, or the like.

The physical object in the present aspect example is a building. A building is constructed based on design data generated in advance. Examples of the design data include BIM data, a design specification, a construction drawing, a working drawing, a working diagram, a construction document, a construction plan, a construction schedule, and the like. The building data recorded in the design data (and/or the building data obtained by processing the design data) in the present disclosure may be referred to as a virtual building, and a structural element or a component (building material) of the virtual building may be referred to as a virtual material. In some aspect examples, the virtual material is a material model provided by a BIM model, and a building structured or configured using a plurality of material models is a virtual building.

In addition, a real building constructed based on design data may be referred to as a physical building, and a structural element or a component (building material) of the physical building may be referred to as a physical material in the present disclosure. The aforementioned physical object corresponds to such a physical building. The physical building may not only be a building completed based on design data, but also be a building under construction (an uncompleted building), or even be a building site before construction taking place.

The building materials in the present disclosure may include structural materials as well as non-structural materials, various kinds of parts, various kinds of machines, various kinds of devices or equipment, various kinds of facilities, and the like. Here, examples of the structural materials include columns, beams, walls, slabs, roofs, foundations, and the like, and examples of the non-structural materials include windows, doors, stairs, tiles, floorings, and the like. More generally, a building material in the present disclosure may be any type of thing or object that can be registered as a virtual material, and may be any type of thing or object that can be used as a physical material.

The memory 14 is configured to store various kinds of data (information). The memory 14 stores, for example, data acquired by the data acquiring unit 13. The memory 14 includes a storage device that has a relatively large capacity (e.g., memory, secondary storage) such as a hard disk drive (HDD) or a solid state drive (SSD), for example. The memory 14 includes a single storage device or two or more storage devices. In the present aspect example, the memory 14 stores the design data 141 and the physical material data 142.

The design data 141 may be any data and/or any information relating to building design. The design data 141 may include, for example, BIM data, a design specification, a construction drawing, a working drawing, a working diagram, a construction document, a construction plan, a construction schedule, and the like. Further, the design data 141 may include data generated from any one or more pieces of data among any data and/or any information relating to building design such as BIM data, a design specification, a construction drawing, a working drawing, a working diagram, a construction document, a construction plan, a construction schedule.

The design data 141 in some aspect examples may be data of a virtual building (a plurality of virtual materials) designed using a BIM application (a BIM tool) that is arranged outside the system 1.

The design data 141 of the present aspect example includes virtual material information. The virtual material information includes information on a plurality of virtual materials that are structural elements or components of a virtual building. More specifically, the virtual material information includes information relating to a plurality of attributes set in advance for each of the plurality of the virtual materials. The attributes mean properties, features, characteristics, or the like of the virtual materials.

In some aspect examples, the plurality of the attributes of the virtual materials includes, for example, virtual material identification information (virtual material ID), virtual material shape information, virtual material position information, material installation date information, and the like. Note that the attributes of the virtual materials are not limited to these items, and may be any types of property, feature, or characteristic such as a raw material, an ingredient, a constituent, a substance, or the like.

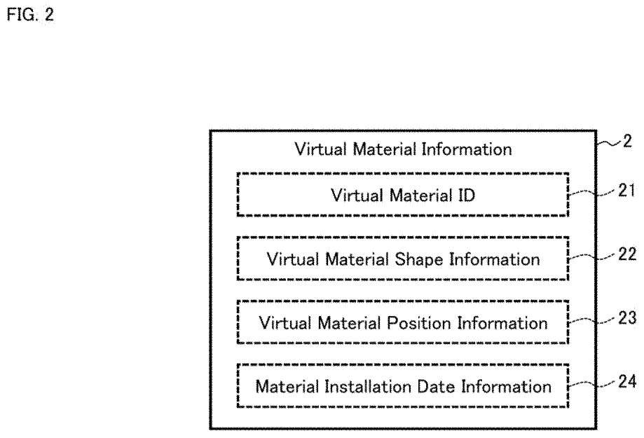

FIG. 2 shows an example of the virtual material information. The virtual material information 2 according to the present example includes the virtual material ID 21, the virtual material shape information 22, the virtual material position information 23, and the material installation date information 24.

The virtual material ID 21 is information for identifying individual virtual materials. The virtual material ID 21 indicates the types of virtual materials (e.g., column, beam, wall, slab, roof, foundation, window, door, stair, tile, flooring, part, machine, device, equipment, facility, or the like). The virtual material ID 21 may be, for example, identification information given to each physical material (material number or the like). The virtual material ID 21 is acquired from BIM data, a design specification, a construction drawing, a working drawing, a working diagram, a construction document, or the like, for example. Further, the virtual material ID 21 may be individually unique identification information. Examples of such virtual material ID 21 include identification information provided in conformity with the Industry Foundation Classes (IFC), which is a file format of a neutral and open CAD data model.

The virtual material shape information 22 is information representing the shape of a virtual material. The virtual material shape information 22 may also include information representing the orientation, direction, posture, or the like of a virtual material. The virtual material shape information 22 is acquired from BIM data, a design specification, a construction drawing, a working drawing, a working diagram, a construction document, or the like, for example.

The virtual material position information 23 represents the position of a virtual material of a virtual building. The position of a virtual material is represented by, for example, the coordinates of the virtual material in the virtual space (three dimensional virtual space defined by a three dimensional coordinate system) in which the virtual building is defined and designed. The virtual material position information 23 is acquired from BIM data, a design specification, a construction drawing, a working drawing, a working diagram, a construction document, or the like, for example.

The material installation date information 24 indicates the date on which the physical material corresponding to a virtual material is installed at the building site or the construction site (e.g., actual installation date, scheduled installation date, or the like). The material installation date information 24 is obtained from a construction drawing, a working drawing, a working diagram, a construction document, or the like, for example.

The system 1 (e.g., the controller 11 and the memory 14) provides, for example, a design database for managing the design data 141. For example, the design database stores data of a virtual building (a plurality of virtual materials of the virtual building) designed using a BIM application. The design database is configured to manage a plurality of virtual materials included in the virtual building one by one. For example, the design database stores the design data 141 including actual BIM data. The design database may be configured to manage the design data 141 for individual virtual buildings, for example.

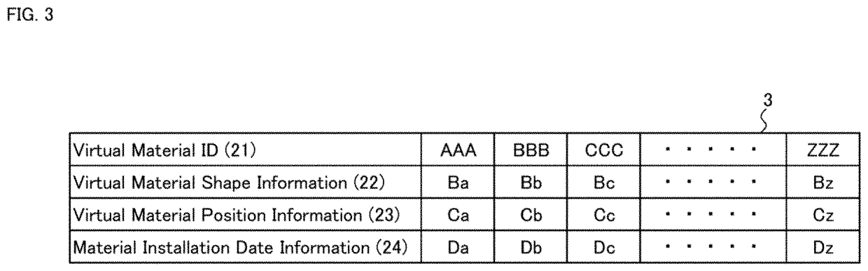

FIG. 3 shows an example of the data structure (data format) of the virtual material information 2 (see FIG. 2) under the management of the design database. The data structure 3 of the present example manages the virtual material information 2 using a table. To be more specific, the table of the data structure 3 may include a virtual material ID section, a virtual material shape information section, a virtual material position information section, and a material installation date information section. The virtual material ID section contains a plurality of cells (or fields) in each of which virtual material ID is entered and recorded. The virtual material shape information section contains a plurality of cells in each of which virtual material shape information is entered and recorded. The virtual material position information section contains a plurality of cells in each of which virtual material position information is entered and recorded. The material installation date information section contains a plurality of cells in each of which material installation date information is entered and recorded. For example, given that a certain virtual material has the virtual material ID 21 “BBB”, the virtual material shape information 22 “Bb”, the virtual material position information 23 “Cb”, and the material installation date information 24 “Da” are being associated with the virtual material ID 21 “BBB” by the data structure 3.

The physical material data 142 may be any type of data and/or any type of information relating to physical materials. The physical material data 142 may be generated based on measured data obtained by measuring a physical building constructed on the basis of the design data 141, for example. Here, the physical building measurement may be conducted by photographing or laser scanning, and the measured data may be a photographed image or point cloud data. The physical building measurement can be performed by the data acquiring unit 13 or an external system. The generation of the physical material data 142 based on the measured data can be executed by the data acquiring unit 13 or an external system. The physical material data 142 may be generated and managed as BIM data in conformity with the same format as the design data 141, for example.

The physical material data 142 includes information on a plurality of physical materials that are structural elements or components of a physical building. More specifically, the physical material data 142 includes information relating to a plurality of attributes set in advance for each of the plurality of the physical materials. The attributes here mean properties, features, characteristics and the like of physical materials.

In some aspect examples, the plurality of the attributes of the physical material corresponds to the plurality of the attributes of the virtual material described above. For example, the plurality of the attributes of the physical material includes physical material identification information (physical material ID), physical material shape information, physical material position information, measurement date information, and the like. It should be noted that the attributes of the physical materials are not limited to these items, and may be any types of property, feature, or characteristic such as a raw material, an ingredient, a constituent, a substance, or the like.

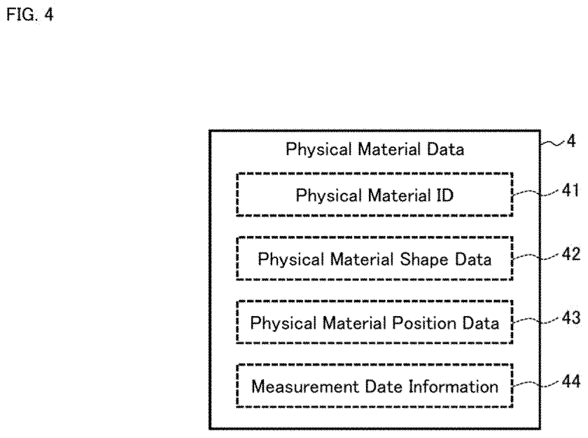

FIG. 4 shows an example of the physical material data. The physical material data 4 according to the present example includes the physical material ID 41, the physical material shape data 42, the physical material position data 43, and the measurement date information 44.

The physical material ID 41 is information for identifying individual physical materials. Similar to the virtual material ID 21, the physical material ID 41 is information indicating the types of physical materials, and may be, for example, identification information given to each physical material (material number or the like). In some aspect examples, identifiers in the physical material ID 41 may respectively be the same as corresponding identifiers in the virtual material ID 21, such as identification information provided by IFC. On the other hand, identifiers in the physical material ID 41 of some aspect examples may respectively be different from corresponding identifiers in the virtual material ID 21, and may be defined in conformity with a predetermined format in which the system 1 (and an external system or the like) is capable of recognizing the relationship between the virtual material ID 21 and the physical material ID 41. The physical material ID 41 is generated in the material associating process described later, for example.

The physical material shape data 42 is data representing the shape of a physical material acquired based on the measured data. The physical material shape data 42 may include data representing the orientation, direction, posture, or the like of a physical material. The physical material shape data 42 is generated in the material associating process described later, for example.

The physical material position data 43 represents the position of a physical material of a physical building. The position of a physical material is represented by, for example, the coordinates of the physical material in the virtual space (three dimensional virtual space defined by a three dimensional coordinate system) in which a BIM model of the physical building created based on the measured data is defined. The physical material position data 43 is generated in the material associating process described later, for example.

The measurement date information 44 indicates the date on which measurement of the physical building is conducted. The measurement date information 44 is generated, for example, by a measurement system (e.g., a mobile object, a total station, a computer, etc.) that performs physical building measurement.

The material installation date information 24 and the measurement date information 44 both include at least information of year, month, and day, and may further include information of hour, minute, second, or the like. The system 1 (or an external system, etc.) may be configured to perform the conversion for representing the material installation date information 24 and the measurement date information 44 in the same standard time in the case where the standard time of the place at which the building design is performed and the standard time of the place at which the physical building exists are different from each other.

The system 1 (e.g., the controller 11 and the memory 14) provides, for example, a physical material database for managing the physical material data 142. For example, the physical material database stores data of a BIM model of a physical building (a BIM model of a plurality of physical materials of the physical building) obtained by processing the measured data of the physical building. The physical material database is configured to manage a plurality of physical material models included in the physical building model one by one. For example, the physical material database stores a physical building BIM model. The physical material database may be configured to manage the physical material data 142 for individual physical building BIM models, for example.

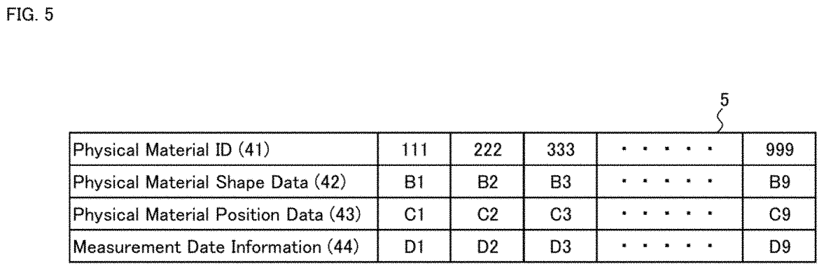

FIG. 5 shows an example of the data structure (data format) of the physical material data 4 (see FIG. 4) under the management of the physical material database. The data structure 5 of the present example manages the physical material data 4 using a table. To be more specific, the table of the data structure 5 may include a physical material ID section, a physical material shape data section, a physical material position data section, and a measurement date information section. The physical material ID section contains a plurality of cells (or fields) in each of which physical material ID is entered and recorded. The physical material shape data section contains a plurality of cells in each of which physical material shape data is entered and recorded. The physical material position data section contains a plurality of cells in each of which physical material position data is entered and recorded. The measurement date information section contains a plurality of cells in each of which measurement date information is entered and recorded. For example, given that a certain physical material has the physical material ID 41 “222”, the physical material shape data 42 “B2”, the physical material position data 43 “C2”, and the measurement date information 44 “D2” are being associated with the physical material ID 41 “222”.

The processor 15 is configured to execute data processing. The processor 15 is implemented, for example, by the cooperation of hardware including a processor and data processing software. The processor 15 may be included in a single computer or decentralized among two or more computers. The processor 15 includes the material associating processor 151 and the attribute associating processor 152.

The material associating processor 151 is configured to determine an association between the plurality of the virtual materials and the plurality of the physical materials based on the virtual material information and the physical material data included in the design data 141. The determination of the association is referred to as a material associating process. The material associating process generates a plurality of pairs of virtual and physical materials. The material associating processor 151 is implemented, for example, by the cooperation of hardware including a processor and material associating software.

An example will be described below of the processing executed by the material associating processor 151. First, the material associating processor 151 matches the coordinate space of the design data 141 and the coordinate space of the physical material data 142 with each other. For example, the material associating processor 151 matches the origin or a predetermined reference point in the coordinate space of the design data 141 and the origin or a predetermined reference point in the coordinate space of the physical material data 142 with each other. In other words, the material associating processor 151 performs registration between the design data 141 and the physical material data 142. The material associating processor 151 of some aspect examples performs registration to determine an association between the coordinate system with which the BIM data (virtual building model) in the design data 141 is defined and the coordinate system with which the BIM data (physical building model) in the physical material data 142 is defined. This enables coordinate conversion between the coordinate system representing the design data 141 and the coordinate system representing the physical material data 142.

Next, the material associating processor 151 performs determination of an association between an object in the design data 141 (e.g., the face, vertex, or center point of a virtual material) and an object in the physical material data 142. For example, the material associating processor 151 may be configured to associate a certain object in the design data 141 and a certain object in the physical material data 142 with each other if the distance between the two objects is less than or equal to a predetermined threshold. Accordingly, physical material position data of that object (physical material) is generated. The physical material position data 43 in FIG. 4 is an example of the physical material position data thus generated.

In addition, the material associating processor 151 may be capable of recognizing the shape of an object in the physical material data 142. For example, the material associating processor 151 may be configured to acquire data representing the shape of a column (surface shape, face shape, cross sectional shape, etc.), the shape of a beam, the shape of a wall, and the shape of a ceiling. Further, the material associating processor 151 may acquire data representing the arrangement (e.g., direction, orientation, posture, etc.) of an object in the physical material data 142. Furthermore, the material associating processor 151 may be configured to recognize the texture, material, raw material, ingredient, constituent, substance, or the like of the surface of an object. The shape, arrangement, texture, material, raw material, ingredient, constituent, substance, or the like is used to generate the physical material shape data (e.g., the physical material shape data 42 in FIG. 4) of that object (physical material). The physical material shape data thus obtained may be used for improving the material associating process (e.g., improving the precision, improving the accuracy) on the basis of distance between objects.

In addition to the above, the material associating processor 151 assigns identification information (identifier) to each physical material identified from the physical material data 142. In other words, the material associating processor 151 may be configured to assign physical material IDs to the physical material data 142.

For example, the material associating processor 151 assigns, to a physical material associated with a certain virtual material, the same identification information as the virtual material ID of that virtual material. In this case, the same identification information is assigned to the pair of the virtual material and the physical material associated with each other. That is, the virtual material and the physical material associated with each other are linked by the same identification information. The identification information commonly assigned to both the virtual material and the physical material may be, for example, unique identification information in conformity with IFC.

In another example, the material associating processor 151 may be configured to assign, to a physical material associated with a certain virtual material, identification information similar to the virtual material ID of that virtual material. For example, a physical material ID consisting of a character string that includes at least part of the character string constituting the virtual material ID of that virtual material, is assigned to the physical material.

In yet another example, the material associating processor 151 may be configured to assign, to a physical material associated with a certain virtual material, unique identification information (physical material ID) and also record the virtual material ID of the virtual material in an additional recording region in the physical material data.

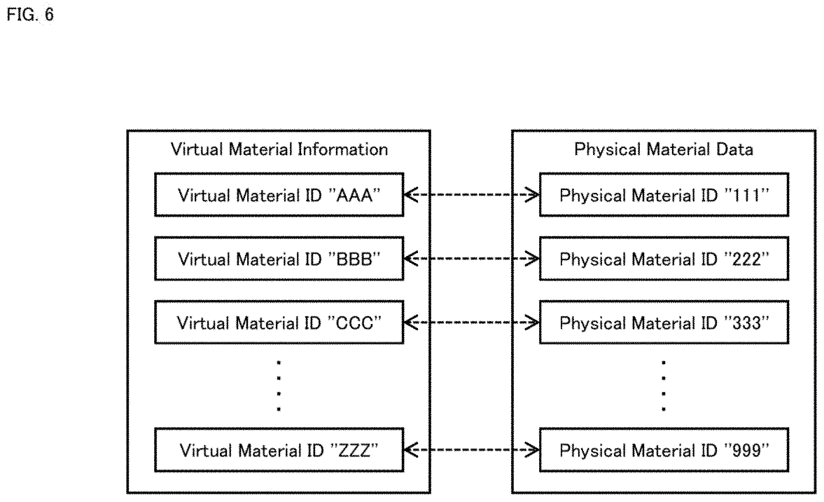

Such a material associating process can establish a correspondence between a plurality of virtual materials and a plurality of physical materials. In other words, a plurality of pairs (material pairs) of the virtual material and the physical material can be obtained by the material associating process. For example, as shown in FIG. 6, the correspondence may be obtained between the plurality of pieces of the identification information of a plurality of virtual materials (virtual material IDs) in the data structure 3 of FIG. 3 and the plurality of pieces of the identification information of a plurality of physical materials (physical material IDs) in the data structure 5 of FIG. 5.

Note that while the correspondence shown in FIG. 6 is a bijection between the set consisting of the plurality of the virtual materials and the set consisting of the plurality of the physical materials, examples of such a correspondence are not limited to a bijection. For example, if there is no physical material in the vicinity of a certain virtual material, that is, if there is no physical material within a range or area of a predetermined distance or less from that virtual material, then there is no physical material to be associated with that virtual material. Conversely, if there is no virtual material in the vicinity of a certain physical material, that is, if there is no virtual material within a range or area of a predetermined distance or less from that physical material, then there is no virtual material to be associated with that physical material. In some aspect examples, if there are two or more physical materials in the vicinity of a certain virtual material, then at least one or more of the two or more physical materials may be associated with that single virtual material. Conversely, if there are two or more virtual materials in the vicinity of a certain physical material, then at least one or more of the two or more virtual materials may be associated with that single physical material. In the case where a correspondence (or a function) other than a bijective function is obtained as in the above example cases, the controller 11 may display the obtained correspondence on the user interface 12, for example. Then, the user may edit the correspondence using the user interface 12.

The attribute associating processor 152 is configured to associate virtual material information and physical material data with each other on the basis of a plurality of attributes, for a material pair (that is, a pair of a virtual material and a physical material) obtained by the material associating processor 151. The attribute associating processor 152 is implemented, for example, by the cooperation of hardware including a processor and attribute associating software.

In some aspect examples, the plurality of the attributes of a virtual material may be the same as the plurality of the attributes of a physical material, for the paired virtual and physical materials. In some aspect examples, the plurality of the attributes of a physical material may include all of the plurality of the attributes of a virtual material, for the paired virtual and physical materials. For example, a metadata structure may be prepared in advance in which common attributes can be registered for virtual material information and physical material data. The attribute associating processor 152 may be configured to utilize the metadata structure to determine an association between the attributes of a virtual material and the attributes of a physical material.

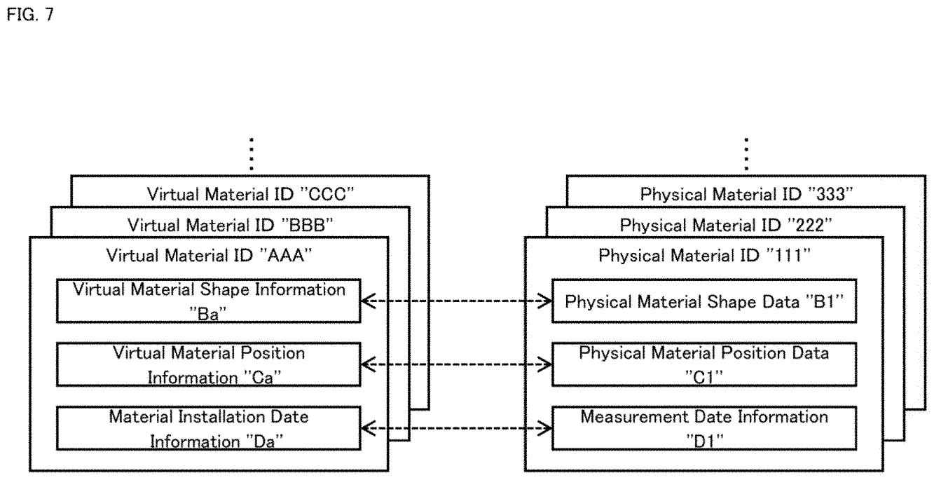

For example, the correspondence is obtained, as shown in FIG. 7, between the plurality of the attributes of each virtual material (each virtual material ID) in the data structure 3 of FIG. 3 and the plurality of the attributes of each physical material (each physical material ID) in the data structure 5 of FIG. 5. In the present example, the following associations are determined for the pair of the virtual material with the virtual material ID “AAA” and the physical material with the physical material ID “111” , for example: the association between the virtual material shape information “Ba” and the physical material shape data “B1”; the association between the virtual material position information “Ca” and the physical material position data “C1”; and the association between the material installation date information “Da” and the measurement date information “D1”. The same applies to other material pairs.

As described above, the system 1 according to the present aspect example is a system used for photogrammetry of a building, and includes the memory 14, the material associating processor 151, and the attribute associating processor 152. The memory 14 records design data that includes virtual material information relating to a plurality of attributes for each of a plurality of virtual materials of a virtual building. Further, the memory 14 records physical material data relating to a plurality of attributes for each of a plurality of physical materials, in which the physical material data is generated based on measured data acquired by measurement of a physical building constructed on the basis of the design data. The material associating processor 151 is configured to perform determination of an association between the plurality of the virtual materials and the plurality of the physical materials based on the virtual material information and the physical material data, thereby generating a plurality of pairs of virtual and physical materials. The attribute associating processor 152 is configured to perform determination of an association between the virtual material information and the physical material data in accordance with the plurality of the attributes, for each of the plurality of pairs generated by the material associating processor 151.

The present aspect example also provides a structure of data (data structure) to be processed by a building photogrammetry system. The data structure includes design data and physical material data. The design data is prepared in advance and includes virtual material information on a plurality of attributes for each of a plurality of virtual materials of a virtual building. The physical material data is generated based on measured data acquired by measurement of a physical building constructed on the basis of the design data, and includes data on the plurality of the attributes for each of a plurality of physical materials of the physical building. The design data and the physical material data are used for a material associating process and an attribute associating process. The material associating process is a process of determining an association between the plurality of the virtual materials and the plurality oldie physical materials based on the virtual material information and the physical material data. The attribute associating process is a process of determining an association between the virtual material information and the physical material data in accordance with the plurality of the attributes, for each of a plurality of pairs of virtual and physical materials established by the material associating process. In addition, the present aspect example is capable of providing a computer-readable non-transitory recording medium in which data having the structure described above is recorded. The non-transitory recording medium may be any of a magnetic disk, an optical disk, a magneto-optical disk, and a semiconductor memory, for example.

In addition, the virtual material information 2 of the system 1 of the present aspect example may include the virtual material position information 23 and the physical material data 4 may include the physical material position data 43. If this is the case, the material associating processor 151 may be configured to generate a plurality of pairs of a virtual material and a physical material based on the virtual material position information 23 and the physical material position data 43.

This configuration example provides a data structure having the following characteristics or features: the virtual material information 2 includes the virtual material position information 23; the physical material data 4 includes the physical material position data 43; and the virtual material position information 23 and the physical material position data 43 are used for the material associating process.

Further, the virtual material information 2 of the system 1 of the present aspect example may include the material installation date information 24 indicating the installation date for each of the plurality of the virtual materials, and the physical material data 4 may include the measurement date information 44 indicating the measurement date of the physical building. Further, the material associating processor 151 may be configured to generate a plurality of pairs of a virtual material and a physical material based on the material installation date information 24 and the measurement date information 44.

This configuration example provides a data structure that has the following characteristics or features: the virtual material information 2 includes the material installation date information 24 indicating the installation date for each of the plurality of the virtual materials; the physical material data 4 includes the measurement date information 44 indicating the measurement date of the physical building; and the material installation date information 24 and the measurement date information 44 are used for the material associating process.

In the case of using the material installation date information 24 and the measurement date information 44, the association may be performed between a plurality of pieces of virtual material information corresponding to a plurality of different installation dates and a plurality of pieces of physical material data corresponding to a plurality of different measurement dates, by checking the material installation dates and the measurement dates against each other. For example, for a certain installation date, the material associating processor 151 may select a measurement date closest to this installation date from among one or more measurement dates after this installation date. Then, the material associating processor 151 may associate physical material data corresponding to the selected measurement date with the virtual material information corresponding to this installation date. As a result of this, a virtual material (virtual material information) and a physical material (physical material data) can be associated with each other based on dates. Accordingly, it becomes to be able to implement time series data management according to a construction document, a construction plan, a construction schedule, or the like, for example.

Further, the present aspect example provides a program for causing a computer, which is included in a building photogrammetry system, to function as a data receiving processor, a material associating processor, and an attribute associating processor. The data receiving processor (e.g., the data acquiring unit 13) receives design data and physical material data. The design data includes virtual material information that relates to a plurality of attributes for each of a plurality of virtual materials of a virtual building. The physical material data is generated based on measured data obtained by measurement of a physical building constructed on the basis of the design data, and relates to a plurality of attributes for each of a plurality of physical materials of the physical building. The material associating processor (e.g., the material associating processor 151) performs determination of an association between the plurality of the virtual materials and the plurality of the physical materials, based on virtual material information and physical material data. The attribute associating processor (e.g., the attribute associating processor 152) performs determination of an association between virtual material information and physical material data on the basis of a plurality of attributes for each of a plurality of pairs of a virtual material and a physical material established by the material associating processor. In addition to this, the present aspect example may provide a computer-readable non-transitory recording medium in which such a program is recorded. The non-transitory recording medium may be, for example, any of a magnetic disk, an optical disk, a magneto-optical disk, and a semiconductor memory.

According to the present aspect example as described above, design data of a building and data of a building constructed based on the design data can be associated with each other on a material-by-material basis (or as a series of material-by-material basis) as well as on a material-attribute-by-material-attribute basis.

The virtual material information is information used for facilitation of measurement works and operations of a physical building, and the physical material data is data obtained by the building measurement using the virtual material information. Such determination of associating the virtual material information and the physical material data on the material basis as well as on the attribute basis makes it easy to compare the design data and the actually measured data with each other. For example, comparison between design BIM data and measurement BIM data can be facilitated. Here, the design BIM data is BIM data as design data, and the measurement BIM data is BIM data created based on measured data.

In this way, the present aspect example makes it possible to integrate the managements of various types of data and information, which makes it possible to improve the efficiency and the consistency of the managements.

The configurations described above are merely some examples of embodiments of the present invention, and any modifications (e.g., omission, substitution, replacement, addition, etc.) may be made to the above aspect examples within the scope of the present invention.

### EXPLANATION OF REFERENCE CHARACTERS

1 system

11 controller

12 user interface

13 data acquiring unit

14 memory

141 design data

142 physical material data

15 processor

151 material associating processor

152 attribute associating processor

1. (canceled)

2. A computer-readable non-transitory recording medium that records data to be processed by a building photogrammetry system, wherein
the data has a structure comprising:
design data that includes virtual material information on a plurality of attributes for each of a plurality of virtual materials of a virtual building; and
physical material data on the plurality of the attributes for each of a plurality of physical materials, the physical material data being generated based on measured data acquired from a physical building constructed on the basis of the design data, and
the data is used for:
a material associating process of determining an association between the plurality of the virtual materials and the plurality of the physical materials based on the virtual material information and the physical material data; and
an attribute associating process of determining an association between the virtual material information and the physical material data in accordance with the plurality of the attributes for each of a plurality of pairs of virtual and physical materials determined by the material associating process.

3. A computer-readable non-transitory recording medium that records a program for causing a computer included in a building photogrammetry system, to function as a data receiving processor, a material associating processor, and an attribute associating processor, wherein
the data receiving processor is configured to receive design data and physical material data, the design data including virtual material information on a plurality of attributes for each of a plurality of virtual materials of a virtual building, and the physical material data being on the plurality of the attributes for each of a plurality of physical materials and being generated based on measured data acquired from a physical building constructed on the basis of the design data;
the material associating processor is configured to perform determination of an association between the plurality of the virtual materials and the plurality of the physical materials, based on the virtual material information and the physical material data; and
the attribute associating processor is configured to perform determination of an association between the virtual material information and the physical material data on the basis of the plurality of the attributes for each of a plurality of pairs of a virtual material and a physical material established by the material associating processor.

4. A system for photogrammetry of a building, comprising:
a memory that stores design data and physical material data, the design data including virtual material information on a plurality of attributes for each of a plurality of virtual materials of a virtual building, and the physical material data being on the plurality of the attributes for each of a plurality of physical materials and being generated based on measured data acquired from a physical building constructed on the basis of the design data;
a material associating processor configured to generate a plurality of pairs of virtual and physical materials by determining an association between the plurality of the virtual materials and the plurality of the physical materials based on the virtual material information and the physical material data; and
an attribute associating processor configured to determine an association between the virtual material information and the physical material data in accordance with the plurality of the attributes for each of the plurality of the pairs.
